(19) United States
(12) Patent Application Publication
(10) Pub. No.: US 2012/0312936 A1
(43) Pub. Date: Dec. 13, 2012

(54) HOLDING DEVICE OF TABLET ELECTRONIC DEVICE

(76) Inventor: Ming Hua HUANG, Kaohsiung City (TW)

(21) Appl. No.: 13/177,570

(22) Filed: Jul. 7, 2011

(30) Foreign Application Priority Data
Jun. 13, 2011 (TW) 100210664

(51) Int. Cl. H05K 7/00; F16M 11/10

(52) U.S. Cl. 248/122.1; 248/316.1

(57) ABSTRACT

A holding device is provided for holding a tablet electronic device and includes a retention seat, which has left and right side faces and a lower face at each of which a clamping member is provided. Each clamping member has an inner end movably received in an interior space of the retention seat and forms a toothed rack mating a toothed wheel, whereby the clamping members are movable simultaneously. The clamping members have outer ends forming pawls extending beyond side faces of the retention seat, whereby with the tablet electronic device positioned on the holding device, the clamping members are moved to have pawls thereof engaging and thus retaining the tablet electronic device in position without undesirably falling off the holding device and thus being damaged.

### (a) TECHNICAL FIELD OF THE INVENTION

The present invention generally relates to a holding device for holding a tablet electronic device, and more particularly to a holding device that receives and securely retains a tablet electronic device (such as a tablet computer, an electronic book, and a personal digital assistant (PDA)) in position and protects the tablet electronic device against undesirably falling and being damaged.

### (b) DESCRIPTION OF THE PRIOR ART

With the fast progress of information technology, various electronic information appliances are increasingly being developed and upgraded, following the trend of being compact and light-weighted for easy carrying and use. Examples of such electronic appliances include tablet computers, electronic books, and personal digital assistants. However, to be compact in size and light in weight, the evolution of such electronic appliances generally leads to such a consequence that no support frame is attached to such an electronic appliance for setting the appliance in an upright erected or inclined fashion and as a result, these tablet electronic devices are only useful in such a way of being placed flat on for example a desk top or being held by a user's hand. This makes the use of such tablet electronic devices very inconvenient.

Diverse solutions for such a problem are available, which provide generally various structures of support frame that position a tablet electronic device in an erected or inclined fashion, such as Taiwan Utility Models M240510, M246976, M262639, M377517, M392290, and M397463. However, the support frames that are disclosed in the prior art references generally comprise a holding device on which a tablet electronic device is positionable and a stand that is pivotally attached to the holding device. Such known support frames are helpful in holding a tablet electronic device in an erected or inclined fashion for easy use and effectively improve the inconvenience that a tablet electronic device can be used by being positioned flat on a desk top or being held by a user's hand. However, such known holding devices provided in the prior art references comprise no structure or arrangement for securely retaining a tablet electronic device positioned thereon and consequently, the tablet electronic device, when positioned on a conventional holding device, may easily fall off the holding device due to accident impact of an external force. This causes inconvenience of the tablet electronic device and may even causes damage of the device.

### SUMMARY OF THE INVENTION

An objective of the present invention is to overcome the drawbacks of the above-described conventional support frame of tablet electronic device and provides an improvement of a holding device of the support frame and the present invention provides a holding device that receives and retains a tablet electronic device thereon to prevent the tablet electronic device from falling and thus being damaged.

To achieve the above objective, the present invention provides a holding device for securely holding a tablet electronic device. The holding device comprises a retention seat, a left clamping member; a right clamping member, and a lower clamping member.

The retention seat comprises a hollow seat structure composed of a front panel and a rear panel, whereby the retention seat has an interior space that receives the left clamping member, the right clamping member, and the lower clamping member therein in an extendable/retractable manner. A rotatable toothed wheel is arranged at a central portion of the interior space of the retention seat.

The left clamping member and the right clamping member have inner end sections that are respectively received in left-hand portion and right-hand portion of the interior space of the retention seat. The inner end section of each of the left clamping member and the right clamping member forms a toothed rack. The toothed racks are in mating engagement with the toothed wheel, whereby the left clamping member and the right clamping member are selectively moveable outward and inward in a simultaneous manner. The left clamping member and the right clamping member have outer ends forming pawls that are respectively located outside left-hand and right-hand side faces of the retention seat.

The lower clamping member has an inner end section received in a lower portion of the interior space of the retention seat. The inner end section of the lower clamping member forms a toothed rack. The toothed rack is in mating engagement with the toothed wheel, whereby when the left clamping member and the right clamping member are simultaneously moved outward or inward, the lower clamping member is simultaneously moved upward and downward. The lower clamping member has an outer end forming pawls that are located outside a lower face of the retention seat.

With such a structure, to position the tablet electronic device on the holding device, the left and right clamping members are simultaneously moved inward, while the lower clamping member is moved downward, so that the pawls of the left and right clamping members and the pawls of the lower clamping member are set in engagement with and thus retain the tablet electronic device. As such, the tablet electronic device is prevented from undesirably falling and is thus protected against damage caused by such falling.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is an exploded view of a holding device according to the present invention.

FIG. 2 is a front view of the holding device of the present invention in an assembled form with a front panel being removed.

FIG. 3 is also a front view of the holding device of the present invention with the front panel removed, illustrating a lower clamping member is movable upward and downward for causing leftward and rightward movement of left and right clamping members to clamp an tablet electronic device.

FIG. 4 is an exploded view of a portion of the holding device of the present invention, particularly showing a retention mechanism thereof.

FIG. 5 is a cross-sectional view of the holding device of the present invention with an e operation bar set in a tight engagement condition.

FIG. 5A is an enlarged view of a portion of FIG. 5.

FIG. 6 is a side elevational view illustrating a support frame pivotally attached to a rear panel of the holding device of the present invention.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

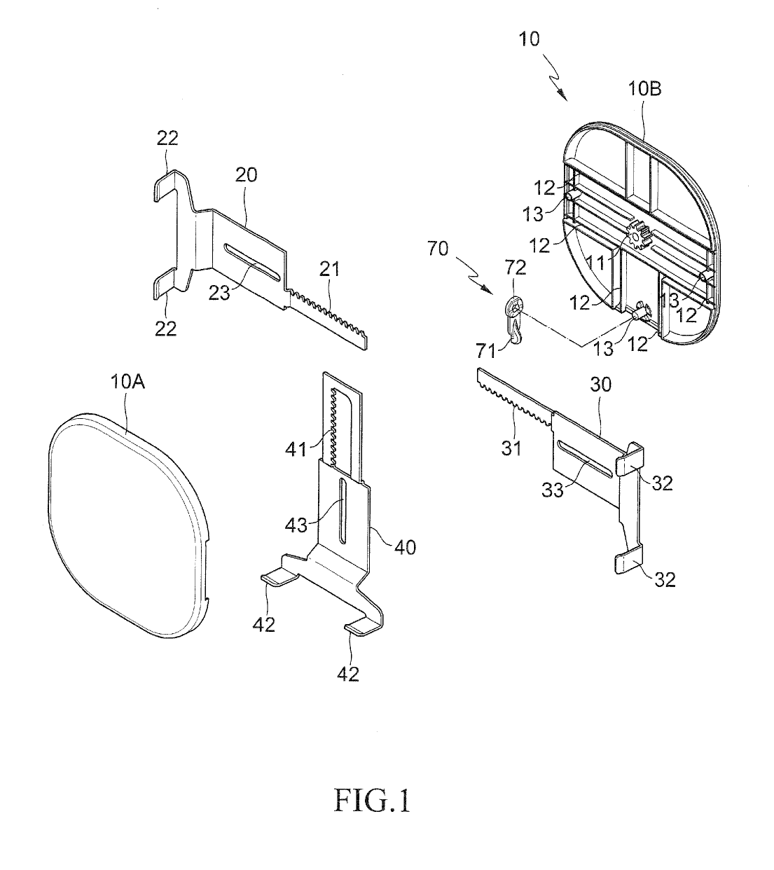

The present invention will now be described in detail with reference to a preferred embodiment illustrated in FIGS. 1-6.

As shown in FIG. 1, a holding device constructed according to the preferred embodiment of the present invention provides comprises a retention seat 10, a left clamping member 20, a right clamping member 30, and a lower clamping member 40.

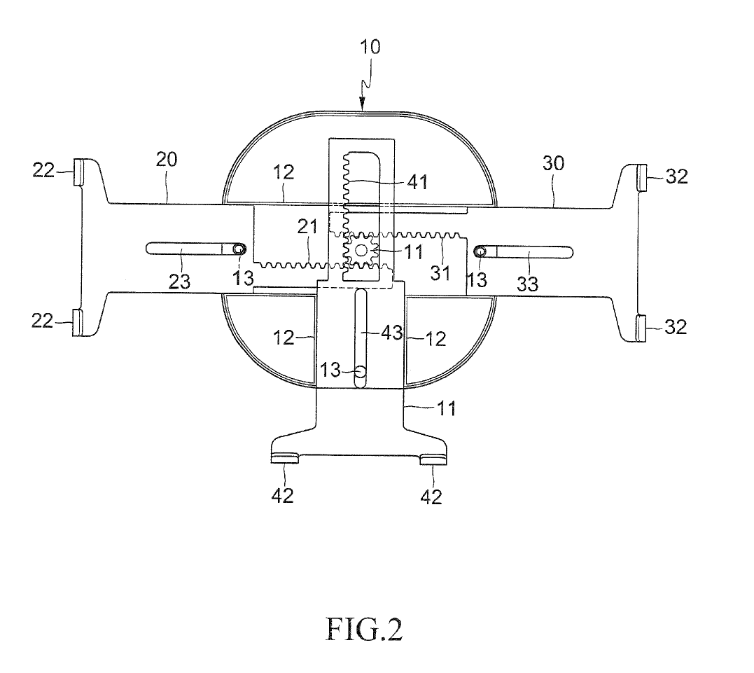

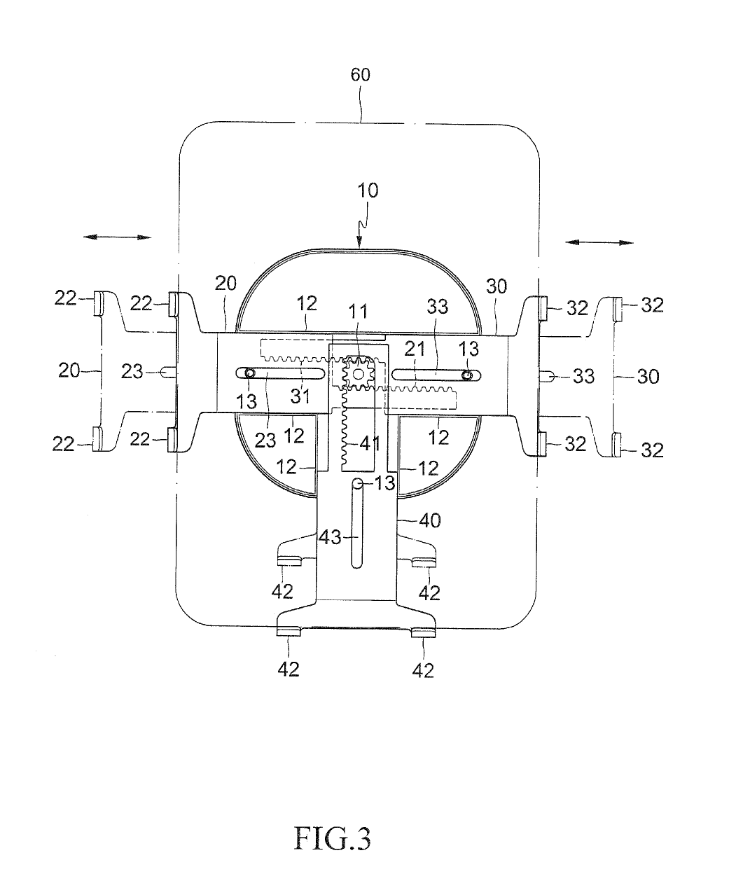

The retention seat 10 (also see FIGS. 2 and 3) comprises a hollow seat structure composed of a front panel 10A and a rear panel 10B. The retention seat 10 has an interior space that receives the left clamping member 20, the right clamping member 30, and the lower clamping member 40 therein in an extendable/retractable manner. Arranged at a central portion of the interior space of the retention seat 10 is a position-fixed but rotatable toothed wheel 11. (In the embodiment illustrated, the toothed wheel 11 is mounted to the rear panel 10B.)

For the preferred embodiment described above, as shown in FIG. 1, the retention seat 10 forms, in the interior space thereof, positioning walls 12 and constraint pegs 13. (In the embodiment illustrated, the positioning walls 12 and the constraint pegs 13 are formed on or mounted to the rear panel 10B.) The positioning walls 12 function to position the left clamping member 20, the right clamping member 30, and the lower clamping member 40 and guide leftward and rightward sliding movements of the left clamping member 20 and the right clamping member 30 and upward and downward sliding movement of the lower clamping member 40. The constraint pegs 13 function to constrain movement strokes of the left clamping member 20, the right clamping member 30, and the lower clamping member 40.

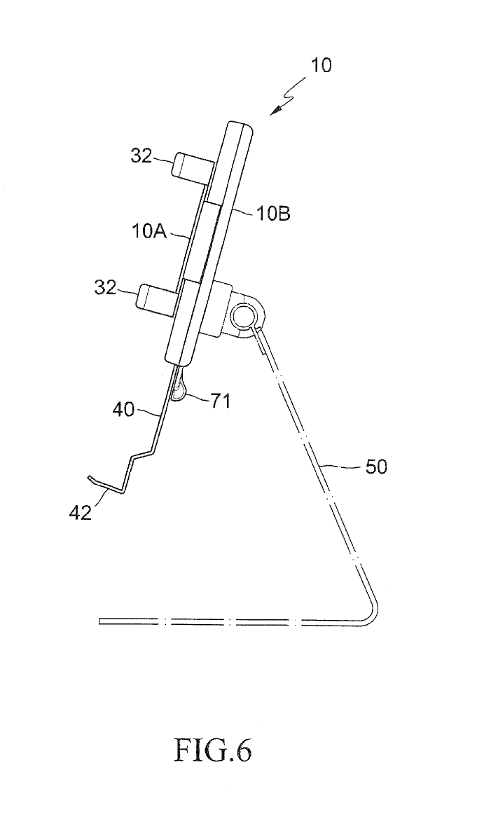

For the preferred embodiment described above, as shown in FIG. 6, the rear panel 10B has a rear surface to which a support frame 50 is selectively and pivotally attached. The support frame 50 supports the retention seat 10 and a tablet electronic device 60 received in and retained by the retention seat 10. The support frame 50 also provides a function of adjusting inclination of the retention seat 10 to provide a desired eyesight angle for the tablet electronic device 60 positioned on the retention seat 10.

Moreover, in the preferred embodiment, the support frame 50 is embodied as an on-desk support frame, but it can be embodied as a support frame of different configuration (such as a wall-mounted support frame or a suction-carried support frame). However, since the support frame is not a novel part of the present invention, no further detail of the support frame will be given herein, unless it is associated with the embodiment of the present invention.

The left clamping member 20 and the right clamping member 30 (also see FIGS. 2 and 3) have inner end sections that are respectively received in left-hand portion and right-hand portion of the interior space of the retention seat 10 and are slidable leftward and rightward within and as being guided by the respective positioning walls 12. The inner end section of each of the left clamping member 20 and the right clamping member 30 forms a toothed rack 21, 31. The two toothed racks 21, 31 both engage the toothed wheel 11, whereby the left clamping member 20 and the right clamping member 30 are moveable outward and/or inward in a simultaneous manner. Further, the left clamping member 20 and the right clamping member 30 each have an outer end forming pawls 22, 32 that are located outside the left-hand or right-hand side face of the retention seat 10.

For the preferred embodiment described above, as shown in FIG. 1, the left clamping member 20 and the right clamping member 30 each form a constraint slot 23, 33 and the constraint slots 23, 33 respectively and movably receive therein the constraint pegs 13 formed in the interior space of the retention seat 10 to serve as a constraint to the movement strokes of the left clamping member 20 and the right clamping member 30.

The lower clamping member 40 (also see FIGS. 2 and 3) has an inner end section received in a lower portion of the interior space of the retention seat 10 and is slidable upward and downward within and as being guided by the respective positioning walls 12. The inner end section of the lower clamping member 40 forms a toothed rack 41, and the toothed rack 41 engages the toothed wheel 11, whereby when the left clamping member 20 and the right clamping member 30 are simultaneously moved outward or inward, the lower clamping member 40 may be simultaneously moved upward and downward. The lower clamping member 40 has an outer end forming pawls 42 that are located outside the lower face of the retention seat 10.

For the preferred embodiment described above, as shown in FIG. 1, the lower clamping member 40 forms a constraint slot 43, and the constraint slot 43 movably receive therein the respective constraint peg 13 formed in the interior space of the retention seat 10 to serve as a constraint to the movement stroke of the lower clamping member 40.

With the structure described above, as shown in FIG. 3, to retain a tablet electronic device 60 on the holding device 10, the left and right clamping members 20, 30 are simultaneously moved inward, while the lower clamping member 40 is moved downward so that the pawls 22, 32 of the left and right clamping members 20, 30 and the pawls 42 of the lower clamping member 40 may engage and hold the tablet electronic device 60 and retain the tablet electronic device 60 in position without undesirably falling and being damaged. For removal, the left and right clamping members 20, 30 are moved outward simultaneously to release and disengage the pawls 22, 32 from the tablet electronic device 60, whereby the tablet electronic device 60 can be removed from the holding device 10.

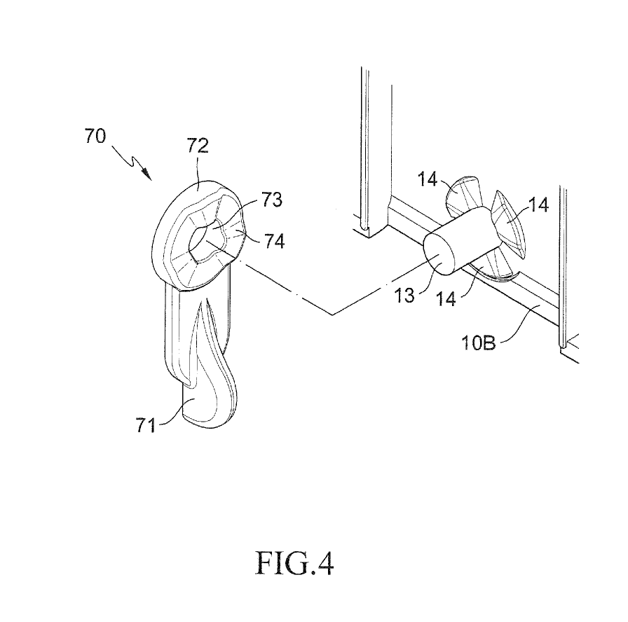

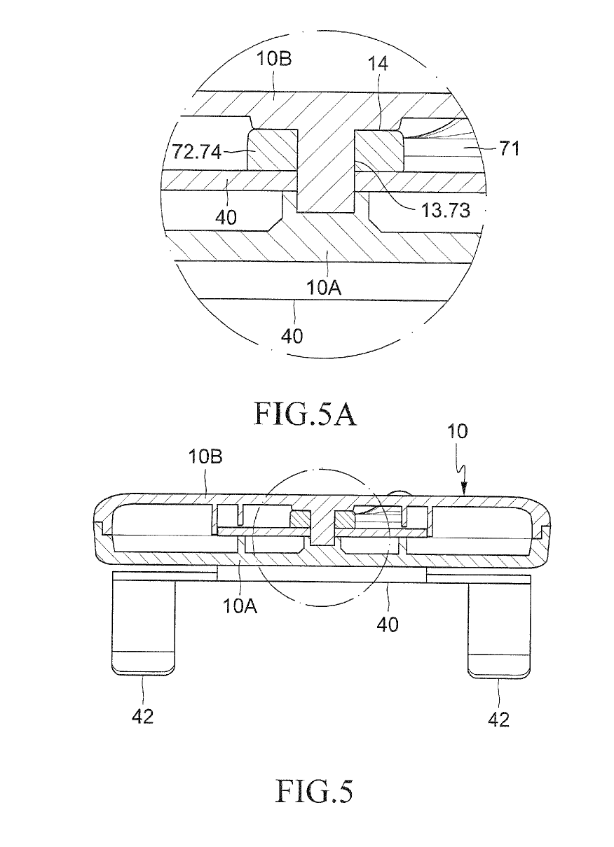

As shown in FIG. 4, the present invention may further comprise a retention mechanism 70, which comprises an operation bar 71. The operation bar 71 has an end extending beyond the lower face of the retention seat 10 and an opposite end forming a circular disc 72. Formed centrally in the circular disc 72 is a circular bore 73, which is sized to snugly fit over the constraint peg 13 of the lower clamping member 40, whereby the operation bar 71 is rotatable about the constraint peg 13. The circular disc 72 and the retention seat 10 have surfaces opposing each other and the surfaces form projecting blocks 74, 14 that are circumferentially arranged in a serrated or wavy form. Manually rotating the operation bar 71 causes rotation of the circular disc 72 about the constraint peg 13, whereby tight and securing engagement selectively formed between the projecting blocks 74, 14 of the circular disc 72 and the retention seat 10 (see FIGS. 5 and 5A) may releasably retain the lower clamping member 40 in position without undesired upward/downward movement, allowing the left clamping member 20, the right clamping member 30, and the lower clamping member 40 to securely retain the tablet electronic device 60.

In summary, it is clear from the embodiment illustrated in the above description and the attached drawings that the present invention allows a tablet electronic device to be securely and effectively retained on the holding device without undesired falling and thus damaged caused by the falling. Further, due to the simultaneous and inter-linked movements of the left clamping member 20, the right clamping member 30, and the lower clamping member 40, the present invention is applicable to tablet electronic devices of various sizes and configurations.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A holding device adapted to retain a tablet electronic device thereon, the holding device comprising a retention seat, a left clamping member, a right clamping member, and a lower clamping member, wherein:
the retention seat comprises a hollow seat structure composed of a front panel and a rear panel, whereby the retention seat has an interior space that receives the left clamping member, the right clamping member, and the lower clamping member therein in an extendable/retractable manner, a rotatable toothed wheel being arranged at a central portion of the interior space of the retention seat;
the left clamping member and the right clamping member have inner end sections that are respectively received in left-hand portion and right-hand portion of the interior space of the retention seat, the inner end section of each of the left clamping member and the right clamping member forming a toothed rack, the toothed racks being in mating engagement with the toothed wheel, whereby the left clamping member and the right clamping member are selectively moveable outward and inward in a simultaneous manner, the left clamping member and the right clamping member having outer ends forming pawls that are respectively located outside left-hand and right-hand side faces of the retention seat; and
the lower clamping member has an inner end section received in a lower portion of the interior space of the retention seat, the inner end section of the lower clamping member forming a toothed rack, the toothed rack being in mating engagement with the toothed wheel, whereby when the left clamping member and the right clamping member are simultaneously moved outward or inward, the lower clamping member is simultaneously moved upward and downward, the lower clamping member having an outer end forming pawls that are located outside a lower face of the retention seat;
whereby with an operation to simultaneously move the left and right clamping members inward and simultaneously move the lower clamping member downward, the pawls of the left and right clamping members and the lower clamping member are set in engagement with and thus retain the tablet electronic device.

2. The holding device according to claim 1, wherein the retention seat forms, in the interior space thereof, positioning walls, which position and guide leftward and rightward movements of the left clamping member and the right clamping member and position and guide upward and downward movement of the lower clamping member.

3. The holding device according to claim 1, wherein the retention seat forms in the interior space thereof constraint pegs, the constraint pegs respectively corresponding to constrain slots formed in the left clamping member, the right clamping member, and the lower clamping member, whereby the constraint pegs are respectively and movably received in the constraint slots to serve as a constraint to movement strokes of the left clamping member, the right clamping member, and the lower clamping member.

4. The holding device according to claim 1, further comprising a retention mechanism, which comprises an operation bar, the operation bar having an end extending beyond a lower face of the retention seat and an opposite end forming a circular disc, a circular bore being formed centrally in the circular disc and the circular bore being snugly fit over the constraint peg of the lower clamping member, whereby the operation bar is rotatable about the constraint peg, the circular disc and the retention seat having surfaces opposing each other and the surfaces forming projecting blocks that are circumferentially arranged in a wavy form so that manually rotating the operation bar causes rotation of the circular disc about the constraint peg and tight and securing engagement is selectively formed between the projecting blocks of the circular disc and the retention seat to releasably retain the lower clamping member in position without undesired upward/downward movement, allowing the left clamping member, the right clamping member, and the lower clamping member to securely retain the tablet electronic device.

5. The holding device according to claim 1, wherein the rear panel is pivotally attached to a support frame.
